(19) United States
(12) Patent Application Publication
(10) Pub. No.: US 2010/0301354 A1
(43) Pub. Date: Dec. 2, 2010

(54) LIGHT EMISSION DEVICE AND DISPLAY DEVICE USING THE SAME

(76) Inventor: Ki-Hyun Noh, Suwon-si (KR)

Correspondence Address: CHRISTIE, PARKER & HALE, LLP, PO BOX 7068, PASADENA, CA, 91109-7068, US

(21) Appl. No.: 12/780,694

(22) Filed: May 14, 2010

(30) Foreign Application Priority Data
May 26, 2009 (KR) 10-2009-0046033

(51) Int. Cl. H01L 33/48

(52) U.S. Cl. 257/88; 257/E33.056; 257/E33.061; 257/E33.067

(57) ABSTRACT

A light emission device includes: a substrate body having a plurality of concave portions recessed into the substrate body and extending along a first direction; a plurality of first electrodes in the plurality of concave portions and extending along the first direction; a plurality of electron emission units on the first electrodes; a plurality of second electrodes on a front surface of the substrate body and extending along a second direction crossing the first electrodes; a plurality of magnetic induction metallic films disposed between the front surface of the substrate body and the second electrodes to contact the front surface and the second electrodes; and a magnetic sheet on a rear surface of the substrate body.

### CROSS-REFERENCE TO RELATED APPLICATION

This application claims priority to and the benefit of Korean Patent Application No. 10-2009-0046033, filed in the Korean Intellectual Property Office on May 26, 2009, the entire content of which is incorporated herein by reference.

### BACKGROUND

1. Field

The following description relates generally to a light emission device and a display device using the same.

2. Description of the Related Art

A light emission device for emitting light may be a light emission device using a field emission effect. A light emission device using the field emission effect may include a front substrate formed with a phosphor layer (or a fluorescent layer) and an anode electrode thereon, and a rear substrate formed with an electron emission unit and driving electrodes thereon. Here, edges (or edge portions) of the front substrate and the rear substrate are integrally joined to each other by a sealing member and an inner space is evacuated to from a vacuum container (vacuum chamber) together with the sealing member.

In one embodiment, the driving electrodes include a cathode electrode and a gate electrode spaced apart from the cathode electrode and extending in a direction crossing the cathode electrode. In addition, an opening is formed on the gate electrode at a crossing region of the cathode electrode and the gate electrode, and the electron emission unit (electron emission region) is disposed on the cathode electrode to be spaced apart from the gate electrode.

By this configuration, when a set or predetermined driving voltage is applied to the cathode electrode and the gate electrode, an electric field is formed around the electron emission unit by a difference in voltage between the two electrodes to emit electrons from the electron emission unit. The emitted electrons collide with the phosphor layer by being induced by high voltage applied to the anode electrode to excite the phosphor layer, such that the phosphor layer emits visible light.

In addition, a structure in which a mesh unit is disposed on the electron emission unit in order to effectively reduce or minimize a divergence angle of an electron beam emitted from the electron emission unit is known. The mesh unit may be fixedly joined with the gate electrode or may be formed integrally with the gate electrode.

However, in such a structure, it is difficult to stably fix the mesh unit. Further, when the mesh unit is deformed by thermal processing during a manufacturing process, charging, arc discharging, etc., are generated in the deformed mesh unit, thereby deteriorating the uniformity of light emitted by the light emission device.

The above information disclosed in this Background section is only for enhancement of understanding of the background of the described technology and therefore it may contain information that does not form the prior art that is already known in this country to a person of ordinary skill in the art.

### SUMMARY OF THE INVENTION

Aspects of embodiments of the present invention are directed toward a light emission device that protects (or prevents) uniformity of emitted light from being deteriorated, and a display device using the same.

Aspects of embodiments of the present invention are directed toward a light emission device capable of stably fixing a mesh unit and protecting (or preventing) uniformity of emitted light from being deteriorated, and a display device using the same.

An exemplary embodiment provides a light emission device that includes: a substrate body having a plurality of concave portions recessed into the substrate body and extending along a first direction; a plurality of first electrodes in the plurality of concave portions and extending along the first direction; a plurality of electron emission units on the first electrodes; a plurality of second electrodes on a front surface of the substrate body and extending along a second direction crossing the first electrodes; a plurality of magnetic induction metallic films disposed between the front surface of the substrate body and the second electrodes to contact the front surface and the second electrodes; and a magnetic sheet on a rear surface of the substrate body.

In one embodiment, the magnetic induction metallic films and the first electrodes are formed together using identical material by a same process, and are spaced apart from each other.

In one embodiment, the magnetic induction metallic films are intermittently formed along the first direction.

In one embodiment, the magnetic induction metallic films are spaced apart from each other so that adjacent ones of the second electrodes are not short-circuited with each other through the magnetic induction metallic film.

In one embodiment, a plurality of antistatic films are on the substrate body and between the plurality of second electrodes. The antistatic films may be formed to extend along the second direction in parallel with the second electrode, and each of the antistatic films may be disposed in a spacing region between two of the magnetic induction metallic films. Each of the antistatic films may be made of chromium oxide (Cr2O3). Each of the antistatic films may be made of an oxide film formed with a metal element selected from the group consisting of Cr, Mn, Co, Y, Ni, Zr, Nb, Mo, Hf, Ta, W, and Ru, or an oxide film formed with an alloy containing two or more kinds of metal elements selected from the group consisting of Cr, Mn, Co, Y, Ni, Zr, Nb, Mo, Hf, Ta, W, and Ru.

In one embodiment, each of the second electrodes is formed by a metal plate having a thickness larger than that of each of the first electrodes; each of the second electrodes includes: a mesh unit on a corresponding electron emission unit of the electron emission units at a region crossing a corresponding first electrode of the first electrodes, and a support unit joined with the substrate body while surrounding the corresponding mesh unit; and a corresponding magnetic induction metallic film of the magnetic induction metallic films is in contact with the support unit. The mesh unit may include a plurality of opening portions for passing electrons emitted from the electron emission unit. Each of the concave portions may have a width larger than that of a corresponding first electrode of the first electrodes therein, and a recession depth larger than a sum of a thickness of the corresponding first electrode and a thickness of a corresponding electron emission unit of the electron emission units on the corresponding first electrode. A portion of the substrate body between two of the concave portions may serve as a partition separating two adjacent ones of the first electrodes from each other, and the second electrodes may be spaced apart from the electron emission units.

In one embodiment, the light emission device further includes: an additional substrate body facing the substrate body; and a third electrode and a phosphor layer on a surface of the additional substrate body facing the substrate body.

Another embodiment provides a display device that includes a light emission device according to the above described embodiments, and a display panel displaying an image by receiving light from the light emission device.

In view of the foregoing and according to an embodiment, a light emission device can stably fix a mesh unit and provide uniformity of emitted light.

Further, in one embodiment, a display device can include the light emission device.

### BRIEF DESCRIPTION OF THE DRAWINGS

FIG. 1 is a partial cut perspective view of a light emission device according to a first embodiment;

FIG. 2 is a partial cross-sectional view of a light emission device of FIG. 1;

FIG. 3 is a partial cut perspective view of a light emission device according to a second embodiment;

FIG. 4 is an exploded perspective view of a display device including a light emission device of FIG. 1; and

FIG. 5 is a partial cross-sectional view of a display panel of FIG. 4.

### DETAILED DESCRIPTION

In the following detailed description, only certain exemplary embodiments of the present invention are shown and described, by way of illustration. As those skilled in the art would recognize, the invention may be embodied in many different forms and should not be construed as being limited to the embodiments set forth herein. Like reference numerals designate like elements throughout the specification.

Further, sizes and thicknesses of constituent members shown in the accompanying drawings are given for better understanding and ease of description, but the present invention is not limited to the illustrated sizes and thicknesses.

In the drawings, the thickness of layers, films, panels, regions, etc., may be exaggerated for clarity. It will be understood that when an element such as a layer, film, region, or substrate is referred to as being “on” an other element, it can be directly on the other element or be indirectly on the other element with one or more intervening elements interposed therebetween. In contrast, when an element is referred to as being “directly on” an other element, there are no intervening elements interposed therebetween.

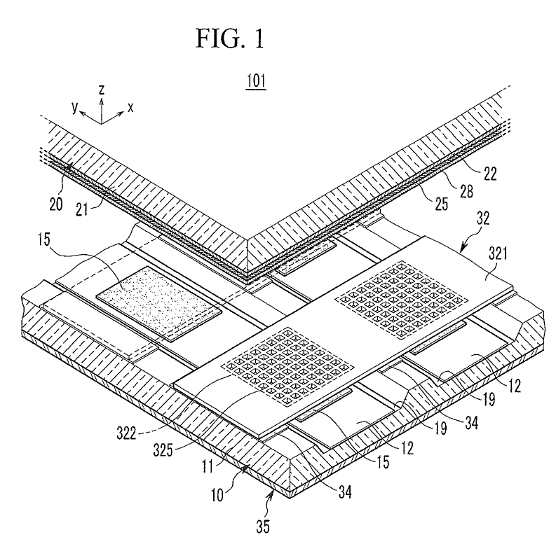

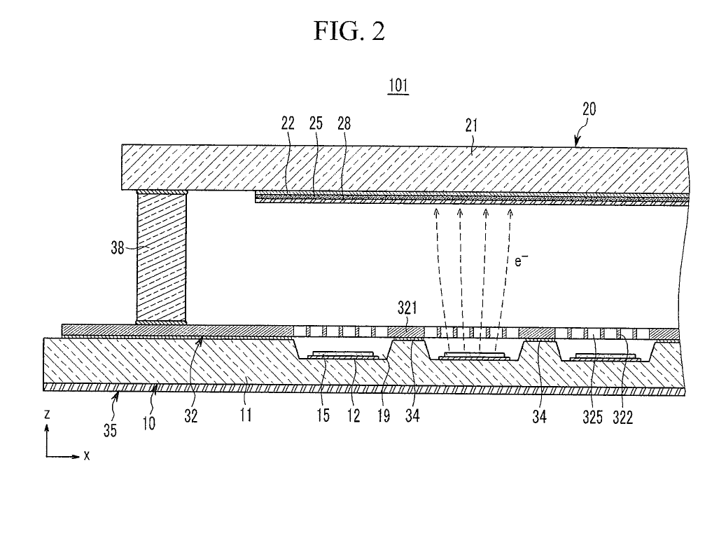

Hereinafter, referring to FIGS. 1 and 2, a light emission device 101 according to a first exemplary embodiment is described below.

As shown in FIG. 1, the light emission device 101 according to the first embodiment includes a first substrate assembly 10, a second substrate assembly 20 facing the first substrate assembly 10, and a sealing member 38 (shown in FIG. 2) that is disposed between the first substrate assembly 10 and the second substrate assembly 20 to bond the two substrate assemblies 10 and 20 to each other. The inner space formed by the first substrate assembly 10, the second substrate assembly 20, and the sealing member 38 is evacuated to be in a vacuum state maintaining a vacuum degree of about 10⁻⁶ Torr.

The first substrate assembly 10 includes a substrate or substrate body (hereinafter, referred to as “first substrate body 11”), a first electrode 12, an electron emission unit 15, a second electrode 32, a magnetic induction metallic film 34, and a magnetic sheet 35. Herein, the first electrode 12 is a cathode electrode, and the second electrode 32 is a gate electrode. However, the first embodiment is not limited thereto. For example, the first electrode 12 may be a gate electrode, and the second electrode 32 may be the cathode electrode in some cases.

The first substrate body 11 includes a plurality of concave portions (recess portions or grooves) 19 recessed into the first substrate body 11 in a stripe pattern. The concave portions 19 are formed by removing a part of the first substrate body 11 by a method such as etching and/or sand blasting. In FIGS. 1 and 2, the concave portion 19 of the first substrate body 11 has an inclined side wall, but the present invention is not limited thereto. For example, the concave portion 19 of the first substrate body 11 may have a vertical side wall.

In one embodiment, the first substrate body 11 has a thickness of about 1.8 mm. Further, the concave portion 19 may have a depth of about 40 μm and a width of 300 to 600 μm.

In one embodiment, multiple first electrodes 12 are disposed on the bottom of the concave portions 19 of the first substrate body 11, respectively. Here, the first electrode 12 is formed in the stripe pattern to extend along a direction (y-axis direction) parallel to the extension direction of the concave portion 19. That is, the length direction (y-axis direction) of the first electrode 12 is the same as the length direction (y-axis direction) of the concave portion 19. In addition, portions of the first substrate body 11 separating the concave portions 19 serve as partitions for separating the adjacent first electrodes 12 from each other.

In one embodiment, multiple second electrodes 32 are formed in the stripe pattern to extend along a direction (x-axis direction) crossing the first electrodes 12, respectively, and are formed on the front surface of the first substrate body 11. Therefore, the second electrode 32 is separated from the first electrode 12 disposed in the concave portion 19 of the first substrate body 11 by approximately the depth of the concave portion 19.

In one embodiment, multiple electron emission units (electron emission regions) 15 are formed on the first electrodes 12 to be spaced from the second electrodes 32, respectively. In FIG. 1, as an example, the electron emission unit (the electron emission region) 15 is formed only at (or in) a region where the first electrode 12 and the second electrode 32 cross each other, but the present invention is not limited thereto. For example, the electron emission unit 15 may be formed on the first electrode 12 in the stripe pattern parallel to the first electrode 12.

The electron emission unit 15 contains materials that emit electrons by being applied with an electric field in a vacuum state, i.e., a carbon-based material and/or a nanometer-sized material. The electron emission unit 15 may contain, for example, carbon nanotubes, graphite, graphite nanofibers, diamond, diamond-like carbon, fullerene (C₆₀), silicon nanowire, and combinations thereof.

The electron emission unit 15 may be constituted by an electron emission layer having a set or predetermined thickness through thick-film processing such as screen printing. That is, the electron emission unit 15 may be formed by processes of screen-printing a paste mixture containing an electron emission material on the first electrode 12, drying and sintering the printed mixture, and activating the surface of the electron emission unit 15 so as to expose the electron emission materials to the surface of the electron emission unit 15. The surface activation process can be made by attaching an adhesive tape and then detaching the same. The electron emission materials such as carbon nanotubes can be substantially vertically erected with respect to the surface of the emission electron unit 15 while removing a part of the surface of the electron emission unit 15 through the surface activation process.

In one embodiment, multiple magnetic induction metallic films 34 are disposed between the front surface of the first substrate body 11 and the second electrodes 32, for example, are disposed to be in contact with the front surface of the first substrate body 11 and the second electrodes 32. The plurality of magnetic induction metallic films 34 are intermittently formed to extend in a direction parallel to the extension direction of the first electrode 12. That is, the plurality of magnetic induction metallic films 34 are arranged while being spaced apart from each other so as not to short-circuit neighboring second electrodes 32 through the magnetic induction metallic films 34 that are in contact with the second electrodes 32.

In one embodiment, a magnetic sheet 35 is disposed on a rear surface of the first substrate body 11, that is, a surface opposite to the surface facing the second electrode 32. The magnetic sheet 35 has magnetism, and serves to fix the second electrode 32 made of a metallic material to the first substrate body 11.

Further, the second electrode 32 includes a mesh unit 322 spaced apart from the first electrode 12 on the electron emission unit 15 in the region crossing the first electrode 12, and a support unit 321 being in contact with the magnetic induction metallic film 34 while surrounding the mesh unit 322. Herein, the mesh unit 322 has a plurality of opening portions 325 for passing electrons emitted from the electron emission unit 15.

Meanwhile, in FIG. 1, the mesh unit 322 of the second electrode 32 is formed only at (or in) a region crossing the first electrode 12, but the present invention is not limited thereto. For example, the mesh unit 322 may be formed even in regions not crossing the first electrode 12 in addition to the region crossing the first electrode 12. In this case, a process of arranging the second electrodes 32 may be more easily performed. Further, a part of the mesh unit 322 may also be in contact with the magnetic induction metallic film 34. In contrast, as shown in FIG. 1, when the mesh unit 322 is formed only in the region crossing the first electrode 12, it is possible to reduce or prevent a voltage drop of the second electrode 32 while the second electrode 32 is being driven by reducing a line resistance of the second electrode 32.

Further, in one embodiment, the second electrode 32 is fabricated by a metal plate having a thickness larger than that of the first electrode 12. For example, the second electrode 32 may be fabricated through a step of forming the opening portion 325 by cutting the metal plate in a stripe pattern and removing a part of the metal plate by using a method such as etching.

The second electrode 32 may be made of a nickel-iron alloy and/or a metallic material other than the alloy, and may be formed to have a thickness of about 50 μm and a width of 10 mm. After the second electrode 32 is fabricated by a process that is different than that of the first electrode 12 and the electron emission unit 15, the second electrode 32 is fixed on the top of the first substrate body 11 to extend in the direction crossing the first electrode 12. Here, since the first electrode 12 and the electron emission unit 15 are positioned in the concave portion 19 of the first substrate body 11, it is possible to naturally (automatically) achieve insulation between the first electrode 12 and the second electrode 32 by only fixing the second electrode 32 to the top of the first substrate body 11.

Further, in one embodiment, the first electrode 12 and the magnetic induction metallic film 34 are made of the same material, and are formed together through the same process. That is, while the first electrode 12 is formed in the concave portion 19 of the first substrate body 11, the magnetic induction metallic film 34 is also formed on the front surface of the first substrate body 11. Here, the first electrode 12 and the magnetic induction metallic film 34 can be made of a metallic material having suitable electrical characteristics. As such, since the magnetic induction metallic film 34 can be fabricated by the same process as the first electrode 12, the magnetic induction metallic film 34 can be formed without an additional process.

By this configuration, the second electrode 32 can be stably fixed to the first substrate body 11. More specifically, the second electrode 32 is fixed to the first substrate body 11 by the magnetic sheet 35. Here, since the second electrode 32 does not directly contact the first substrate body 11 made of an insulating material and instead contacts the magnetic induction metallic film 34 formed just on the first substrate body 11, the magnetic force of the magnetic sheet 35 can effectively function. Accordingly, the second electrode 32 can be more stably fixed to the first substrate body 11. That is, the second electrode 32 can fix the second electrode 32 more stably than a case in which the second electrode 32 directly contacts the first substrate body 11.

Accordingly, embodiments of the present invention protect or minimize the second electrode 32 including the mesh unit 322 from being deteriorated by thermal processing during a manufacturing process. Further, even if the second electrode 32 is deteriorated, embodiments of the present invention can still stably maintain the coupling (or adhesiveness) of the second electrode 32 to the first substrate body 11. That is, charging, arc discharge, etc., are generated due to deterioration of the second electrode 32, and embodiments of the present invention effectively prevent the uniformity of light emitted by the light emission device 101 from being deteriorated by maintaining the coupling (or adhesiveness) of the second electrode 32 to the first substrate body 11.

In addition, the concave portion 19 of the first substrate body 11 has a width larger than the width of the first electrode 12 and has a recession depth larger than the sum of the thickness of the first electrode 12 and the thickness of the electron emission unit 15. Therefore, the second electrode 32 is stably separated from the first electrode 12 disposed in the concave portion 19 of the first substrate body 11. That is, the first electrode 12 and the second electrode 32 are stably insulated from each other.

Further, one crossing region between the first electrode 12 and the second electrode 32 may correspond (or be positioned at) one pixel area of the light emission device 101 or two or more crossing regions may correspond (or be positioned at) one pixel area of the light emission device 101. In the latter case, the first electrodes 12 or the second electrodes 32 corresponding to one pixel area are electrically connected to each other to be applied with the same voltage.

In one embodiment, the second substrate assembly 20 includes a substrate or substrate body (hereinafter, referred to as ‘second substrate body 21’), a third electrode (or an anode electrode) 22, a phosphor layer (or a fluorescent layer) 25, and a reflection film 28. The third electrode 22, the phosphor layer 25, and the reflection film 28 are sequentially formed on an inner surface of the second substrate body 21 facing the first substrate assembly 10. That is, the third electrode 22, the phosphor layer 25, and the reflection film 28 are sequentially arranged adjacent to the second substrate body 21. Herein, the third electrode 22 becomes the anode electrode.

The third electrode 22 is made of a transparent conductive material such as indium tin oxide (ITO) so as to transmit visible light emitted from the phosphor layer 25. The third electrode 22 functions as an acceleration electrode inducing the electron beam, and maintains the phosphor layer 25 in a high-voltage state by being applied with positive direct-current voltage (hereinafter, referred to as ‘anode voltage’) of thousands of volts or more.

The phosphor layer 25 may be formed of a mixed phosphor and/or fluorescent material that can emit white light by mixing a red phosphor and/or fluorescent material, a green phosphor and/or fluorescent material, and a blue phosphor and/or fluorescent material with each other. In FIGS. 1 and 2, the phosphor layer 25 is formed in the entire light emission area of the second substrate body 21, but the present invention is not limited thereto. For example, the phosphor layer 25 may be separately formed in each pixel area.

The reflection film 28 may be composed of an aluminum thin-film having a thickness of thousands of angstroms (Å) and formed with minute holes for passing the electron beam. The reflection film 28 reflects the visible light emitted toward the first substrate 10 among visible lights emitted from the phosphor layer 25 to increase the luminance of the light emission device 101.

In addition, the third electrode 22 or the reflection film 28 may be omitted. In the case where the third electrode 22 is omitted, the reflection film 28 can perform the same function as the third electrode 22 by being applied with the anode voltage.

Further, the light emission device 101 may further include a spacer that constantly maintains a gap between the two substrate assemblies 12 and 14 by countering (or enduring) a vacuum pressure between the first substrate assembly 10 and the second substrate assembly 20.

By this configuration, in pixels where a voltage difference between the first electrode 12 and the second electrode 32 is equal to or larger than a threshold, an electric field is formed around the electron emission unit 15, thereby emitting electrons. The emitted electrons collide with a corresponding portion of the phosphor layer 25 by being induced by the anode voltage applied to the third electrode 22 so as to allow the corresponding phosphor layer 25 to emit the light. The luminance (luminance intensity) of the phosphor layer 25 for each pixel corresponds to the amount of electrons emitted by the corresponding pixel.

As shown in FIG. 2, because the mesh unit 322 of the second electrode 32 is disposed just on the electron emission unit 15, the electrons that are emitted from the electron emission unit 15 pass through the opening portion 325 of the mesh unit 322 in the state of reduced or minimized beam dispersion and reach the phosphor layer 25. Accordingly, the light emission device 101 according to the first embodiment can effectively protect or prevent a side wall of the concave portion 19 from being charged with electric charges by reducing an initial dispersion angle of the electron beam.

As a result, the light emission device 101 according to the first embodiment can stabilize driving by improving withstand voltage characteristics of the first electrode 12 and the second electrode 32 and implement high luminance by applying high voltage of 10 kV or more, and, in one embodiment, a high voltage of 10 to 15 kV to the third electrode 22.

Further, in the case of the light emission device 101 according to the first embodiment, since the thick-film processing for forming the insulating layer and the thin-film processing for forming the second electrode 32 are not needed, it is possible to simplify the manufacturing process. In addition, as described above, since the second electrode 32 can be easily positioned (or disposed) in the light emission device 101, the manufacturing productivity can be improved.

Further, since the second electrode 32 is positioned (or disposed) after forming the electron emission unit 15, it is possible to protect or prevent the first electrode 12 and the second electrode 32 from being short-circuited due to a conductive electron emission material during the formation of the electron emission unit 15 from being in electrical contact with the first electrode 12 and the second electrode 32.

Further, since the second electrode 12 can be stably joined to the first substrate body 11 through the magnetic sheet 35 and the magnetic induction metallic film 34, it is possible to reduce or prevent noise from being generated by suppressing vibration generated due to a driving frequency. In addition, since the height of the opening portion 325 of the mesh unit 322 is constantly fixed, it is possible to improve the uniformity of the luminance. That is, the light emission device 101 can emit uniform light.

By the above described and shown configuration, the light emission device 101 can stably fix the second electrode 32 including the mesh unit 322 and protect (or prevent) the uniformity of the emitted light from being deteriorated.

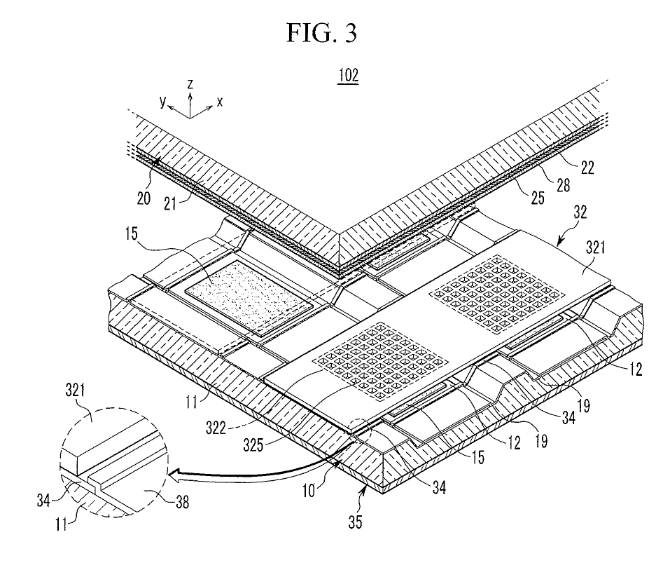

Hereinafter, referring to FIG. 3, a light emission device 102 according to a second embodiment is described below.

As shown in FIG. 3, the light emission device 102 according to the second embodiment further includes a plurality of antistatic films 38 between a plurality of second electrodes 32 on the first substrate body 11. That is, the antistatic film 38 is formed to extend in a direction parallel to the extension direction of second electrode 32 and is disposed in a spacing area between two of the magnetic induction metallic films 34.

The antistatic film 38 is made of a material in which a secondary electron emission coefficient (where electric charge is not generated) is 1 or a material in which the secondary electron emission coefficient is substantially close to 1. For example, the antistatic film 38 can be made of chrome oxide (Cr₂O₃). In the antistatic film 38, a paste containing chrome oxide or a liquid mixture can be suitably formed by using the suitable screen-printing method, a spray application method, or the like. Also, in one embodiment, the antistatic film 38 is made of an oxide film formed with Cr, Mn, Co, Y, Ni, Zr, Nb, Mo, Hf, Ta, W, or Ru. In another embodiment, the antistatic film is made of an oxide film that is an alloy containing two or more kinds of metal elements selected from the group consisting of Cr, Mn, Co, Y, Ni, Zr, Nb, Mo, Hf, Ta, W, and Ru. The antistatic film 12 can be suitably formed by using a sputtering method.

The antistatic film 38 suppresses charging of electric charges generated between the second electrodes 32, between the first electrode 12 and the second electrode 32, between the second electrode 32 and the third electrode (anode electrode) 22, or the like to thereby reduce or prevent arcing, thereby effectively suppressing damage to the electron emission unit 15 and the electrodes 12, 22, and 32. Further, even when a high voltage of about 10 kV or higher is applied to the third electrode 22, arc discharge can be suppressed by the antistatic film 38. Therefore, since this high voltage of about 10 kV or higher can be applied to the third electrode 21, it is possible to increase the luminance.

By the above described and shown configuration, the light emission device 102 can achieve further uniform and/or high luminance.

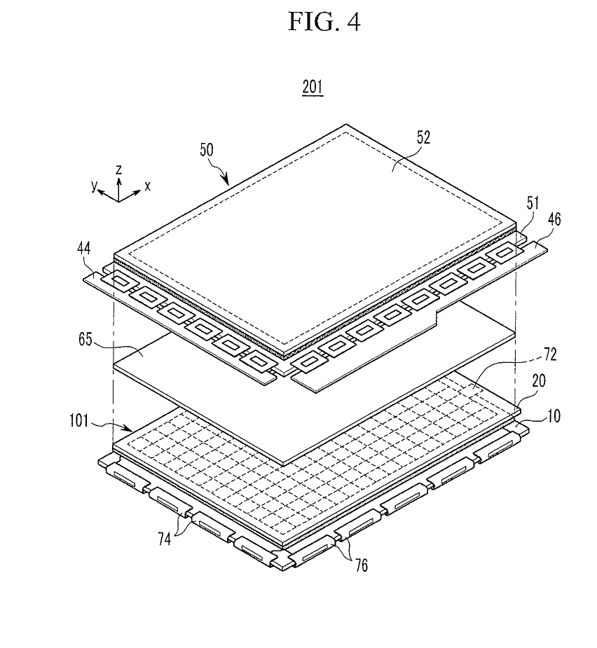

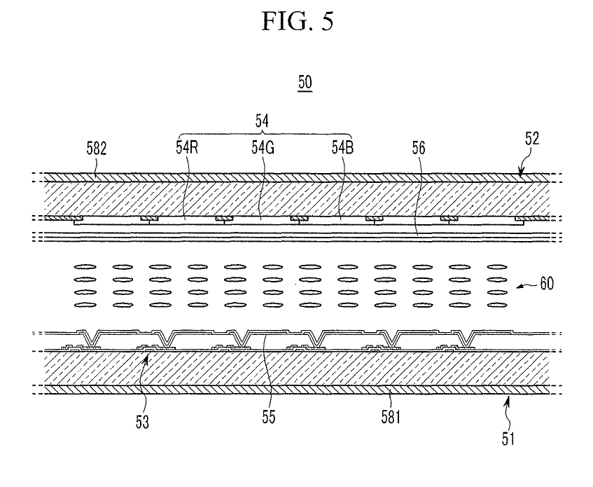

Hereinafter, referring to FIGS. 4 and 5, a display device 201 according to an embodiment is described below. A display device 201 according to the embodiment may include the light emission devices 101 and 102 according to the above-mentioned embodiments. Hereinafter, the display device 201 with the light emission device 101 of FIG. 1 is described below as an example.

As shown in FIG. 4, the display device 201 includes the light emission device 101 and a display panel 50 disposed in front of the light emission device 101. Here, the display device 201 may (or may not) further include a diffusion member 65 that is disposed between the light emission device 101 and the display panel 50 to evenly diffuse light emitted from the light emission device 101. The diffusion member 65 and the light emission device 101 are spaced apart from each other by a set or predetermined distance. The display device 201 includes the light emission device 101 according to the first embodiment as a light source.

In FIGS. 4 and 5, a liquid crystal display panel is used as the display panel 50, but the present invention is not limited thereto. For example, the display panel 50 may be a non-emissive display panel other than the liquid crystal display panel.

As shown in FIG. 5, the display panel 50 includes a first display plate 51 where a thin film transistor (TFT) 53 and a pixel electrode 55 are formed, a second display plate 52 where a color filter layer 54 and a common electrode 56 are formed, and a liquid crystal layer 60 injected between the first display plate 51 and the second display plate 52. Polarizing plates 581 and 582 are respectively attached to a front surface of the first display plate 51 and a rear surface of the second display plate 52 to polarize light passing through the display panel 50.

The pixel electrode 55 is positioned in each of the sub-pixels. Driving of the pixel electrode 55 is controlled by the thin film transistor 53. Herein, a plurality of sub-pixels (e.g., three sub-pixels) implementing different colors are grouped together to constitute one pixel. The pixel is a minimum unit for displaying an image. The pixel electrode 55 and the common electrode 56 are made of a transparent conductive material. The color filter layer 54 includes a red filter layer 54R, a green filter layer 54G, and a blue filter layer 54B that are respectively positioned in the sub-pixels.

When the thin film transistor 53 of a certain sub-pixel is turned on, an electric field is formed between the pixel electrode 55 and the common electrode 56. Array angles of liquid crystal molecules of the liquid crystal layer 60 are changed by the electric field. Light permeability is changed according to the changed array angles of the liquid crystal molecules. The display panel 50 can display an image by controlling luminance and illumination color for each pixel through the process.

Further, the display panel 50 is not limited to the above-mentioned structure, and may be modified in various suitable configurations.

In addition, as shown in FIG. 4, the display device 201 includes a gate circuit substrate 44 supplying a gate driving signal to a gate electrode of each thin film transistor 53 of the display panel 50, and a data circuit substrate 46 supplying a data driving signal to a source electrode of each thin film transistor 53 of the display panel 50.

The light emission device 101 allows one pixel of the light emission device 101 to correspond to two or more pixels of the display panel 50 and is formed to have fewer pixels than that of the display panel 50.

Each pixel of the light emission device 101 can emit light in correspondence with the gray levels of the pixels of the display panel 50 corresponding thereto. For example, each pixel of the light emission device 101 can emit light in correspondence with the highest gray level among the gray levels of the pixels of the display panel 50. Each pixel of the light emission device 101 can display gray levels in a gray-scale of 2 to 8 bits.

Hereinafter, for convenience of description, a pixel of the display panel 50 is referred to as a first pixel, a pixel of the light emission device 101 is referred to as a second pixel, and multiple first pixels corresponding to one second pixel are referred to as a first pixel group.

A driving process of the light emission device 101 may include a step of allowing a signal controller for controlling the display panel 50 to detect the highest gray level among the gray levels of the first pixels of the first pixel group, a step of calculating a gray level required for emitting the second pixel in accordance with the detected gray level and converting the calculated gray level into digital data, a step of generating a driving signal of the light emission device 101 by using the digital data, and a step of applying the generated driving signal to a driving electrode of the light emission device 101.

The driving signal of the light emission device 101 is constituted by a scanning signal and a data signal. Either the first electrode 12 or the second electrode 32 is applied with the scanning signal and the other electrode is applied with the data signal.

Further, a data circuit substrate and a scanning circuit substrate for driving the light emission device 101 may be disposed on a rear surface of the light emission device 101. The data circuit substrate and the scanning circuit substrate are connected to the first electrode 12 and the second electrode 32 through a first connector 76 and a second connector 74, respectively. In addition, a third connector 72 applies the anode voltage to the third electrode 22.

As described above, the second pixel of the light emission device 101 is synchronized with the first pixel group to emit light at a certain or predetermined gray level when the image is displayed in the corresponding first pixel group. That is, the light emission device 101 provides light having high luminance to a bright region in a screen implemented by the display panel 50, and provides light having low luminance to a dark region of the screen. Therefore, the display device 201 according to the embodiment can increase a contrast ratio of the screen and implement clearer image quality.

By the above described and shown configuration, the display device 201 can include the light emission device 101 formed with the stably fixed second electrode 32 including the mesh unit 322 that is capable of protecting and/or preventing the uniformity of the emitted light from being deteriorated.

Further, when utilized with the light emission device 102, the display device 201 can achieve further uniform and/or high luminance as shown and described above with respect to the light emission device 102 of FIG. 3.

While this disclosure has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A light emission device, comprising:
a substrate body having a plurality of concave portions recessed into the substrate body and extending along a first direction;
a plurality of first electrodes in the plurality of concave portions and extending along the first direction;
a plurality of electron emission units on the first electrodes;
a plurality of second electrodes on a front surface of the substrate body and extending along a second direction crossing the first electrodes;
a plurality of magnetic induction metallic films disposed between the front surface of the substrate body and the second electrodes to contact the front surface and the second electrodes; and
a magnetic sheet on a rear surface of the substrate body.

2. The light emission device of claim 1, wherein
the magnetic induction metallic films and the first electrodes are formed together using identical material by a same process, and are spaced apart from each other.

3. The light emission device of claim 1, wherein
the plurality of magnetic induction metallic films are intermittently formed along the first direction.

4. The light emission device of claim 1, wherein
the plurality of magnetic induction metallic films are spaced apart from each other so that adjacent ones of the second electrodes are not short-circuited with each other through the magnetic induction metallic film.

5. The light emission device of claim 1, further comprising
a plurality of antistatic films on the substrate body and between the plurality of second electrodes.

6. The light emission device of claim 5, wherein
the antistatic films are formed to extend along the second direction in parallel with the second electrode, and
each of the antistatic films is disposed in a spacing region between two of the magnetic induction metallic films.

7. The light emission device of claim 5, wherein
each of the antistatic films is made of chromium oxide (Cr₂O₃).

8. The light emission device of claim 5, wherein
each of the antistatic films is made of an oxide film formed with a metal element selected from the group consisting of Cr, Mn, Co, Y, Ni, Zr, Nb, Mo, Hf, Ta, W, and Ru, or an oxide film formed with an alloy containing two or more kinds of metal elements selected from the group consisting of Cr, Mn, Co, Y, Ni, Zr, Nb, Mo, Hf, Ta, W, and Ru.

9. The light emission device of claim 1, wherein
each of the second electrodes is formed by a metal plate having a thickness larger than that of each of the first electrodes;
each of the second electrodes comprises:
a mesh unit on a corresponding electron emission unit of the electron emission units at a region crossing a corresponding first electrode of the first electrodes; and
a support unit joined with the substrate body while surrounding the corresponding mesh unit; and
a corresponding magnetic induction metallic film of the magnetic induction metallic films is in contact with the support unit.

10. The light emission device of claim 9, wherein
the mesh unit comprises a plurality of opening portions for passing electrons emitted from the electron emission unit.

11. The light emission device of claim 1, wherein
each of the concave portions has a width larger than that of a corresponding first electrode of the first electrodes therein, and a recession depth larger than a sum of a thickness of the corresponding first electrode and a thickness of a corresponding electron emission unit of the electron emission units on the corresponding first electrode.

12. The light emission device of claim 11, wherein
a portion of the substrate body between two of the concave portions serves as a partition separating two adjacent ones of the first electrodes from each other, and
the second electrodes are spaced apart from the electron emission units.

13. The light emission device of claim 1, further comprising:
an additional substrate body facing the substrate body; and
a third electrode and a phosphor layer on a surface of the additional substrate body facing the substrate body.

14. A display device, comprising:
a light emission device comprising:
a substrate body having a plurality of concave portions recessed into the substrate body and extending along a first direction;
a plurality of first electrodes in the plurality of concave portions and extending along the first direction;
a plurality of electron emission units on the first electrodes;
a plurality of second electrodes on a front surface of the substrate body and extending along a second direction crossing the first electrodes;
a plurality of magnetic induction metallic films disposed between the front surface of the substrate body and the second electrodes to contact the front surface and the second electrodes; and
a magnetic sheet on a rear surface of the substrate body ; and
a display panel for displaying an image by receiving light from the light emission device.
